(19) United States
(12) Patent Application Publication
(10) Pub. No.: US 2024/0188300 A1
(43) Pub. Date: Jun. 6, 2024

(54) 3D MEMORY INCLUDING HOLLOW EPITAXIAL CHANNELS

(71) Applicant: Applied Materials, Inc., Santa Clara, CA (US)

(72) Inventors: HsiangYu LEE, Cupertino, CA (US); Pradeep SUBRAHMANYAN, Cupertino, CA (US); Changwoo SUN, San Jose, CA (US)

(73) Assignee: Applied Materials, Inc., Santa Clara, CA (US)

(21) Appl. No.: 18/525,633

(22) Filed: Nov. 30, 2023

Related U.S. Application Data
(60) Provisional application No. 63/429,867, filed on Dec. 2, 2022.

(51) Int. Cl. H10B 43/27; H10B 43/10; H10B 43/35

(52) U.S. Cl. CPC H10B 43/27; H10B 43/10; H10B 43/35

(57) ABSTRACT

Disclosed are approaches for fabricating 3D NAND flash memory structures including hollow epitaxial channels. One approach for fabricating a 3D NAND memory structure may include forming a plurality of alternating material layers arranged in a vertical stack on a substrate, etching a channel hole that extends through the plurality of alternating material layers to the substrate, and forming a tunneling layer around the channel hole contacting the plurality of alternating material layers. The method may further include forming a channel liner along the tunneling layer, forming a core gap material within the channel liner, removing the channel liner from the channel hole, and epitaxially growing a hollow epitaxial silicon core from the substrate through the channel hole, between the tunneling layer and the core gap material.

### RELATED APPLICATION

This application claims priority to U.S. provisional patent application Ser. No. 63/429,867, filed on Dec. 2, 2022, entitled “3D Memory Including Hollow Epitaxial Channels,” which is incorporated herein by reference in its entirety.

### FIELD

The present disclosure relates to processing of NAND devices and, more particularly, to approaches for fabricating 3D NAND flash memory structures including hollow epitaxial channels.

### BACKGROUND

A memory design known as NAND memory is a non-volatile flash memory storage architecture that does not require power to maintain its stored data. NAND flash memory is used in many products, such as solid-state devices and portable electronics. In order to improve the density and reduce the size of NAND memories, traditional two-dimensional NAND architectures have transitioned to three-dimensional NAND stacks. Unlike 2D planar NAND technologies where the individual memory cells are stacked together on separate horizontal substrates, 3D NAND is stacked vertically using multiple layers of alternating conducting and dielectric materials with intersecting vertical channels.

Polysilicon is commonly used as a channel material for 3D NANDs. However, as the channel length increases, mobility limitations posed by the polysilicon adversely affect device performance. It is with respect to these and other considerations that the present disclosure is provided.

### SUMMARY OF THE DISCLOSURE

In view of the foregoing, in some approaches, a three-dimensional (3D) NAND memory structure may include a silicon substrate and a plurality of alternating material layers arranged in a vertical stack on the silicon substrate, wherein a channel hole extends through the plurality of alternating material layers to the silicon substrate, and wherein the channel hole is perpendicular to the plurality of alternating material layers. The 3D NAND memory structure may further include a channel inside the channel hole, wherein the channel includes a tunneling layer around an interior of the channel hole contacting the plurality of alternating material layers, and a hollow epitaxial silicon core inside the tunneling layer, wherein the hollow epitaxial silicon core contacts the silicon substrate.

In some approaches, a method may include forming a plurality of alternating material layers arranged in a vertical stack on a substrate, and etching a channel hole that extends through the plurality of alternating material layers to the substrate. The method may further include forming a tunneling layer around the channel hole contacting the plurality of alternating material layers, and forming a channel liner along the tunneling layer. The method may further include forming a core gap material within the channel liner, removing the channel liner from the channel hole, and epitaxially growing a hollow epitaxial silicon core from the substrate through the channel hole, between the tunneling layer and the core gap material.

In some approaches, a method of fabricating a hollow epitaxial silicon core of a three-dimensional (3D) NAND memory structure may include forming a plurality of alternating material layers arranged in a vertical stack on a silicon substrate, etching a channel hole that extends through the plurality of alternating material layers to the silicon substrate, and forming a tunneling layer around the channel hole, wherein the tunneling layer contacts the plurality of alternating material layers. In some embodiments, the method may further include forming a channel liner around the tunneling layer, forming a core gap material within the channel liner, removing the channel liner from the channel hole, and epitaxially growing the hollow epitaxial silicon core from the silicon substrate through the channel hole, between the tunneling layer and the core gap material.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a top plan view of a processing system, according to some embodiments.

FIGS. 2A-2R illustrate incremental stages for generating an array of 3D NAND flash memory cells with hollow epitaxial channels, according to some embodiments.

FIG. 3A illustrates a portion of a memory array, according to some embodiments.

FIG. 3B illustrates a portion of a memory array when the some of the channels have been used for support structures to facilitate the hollow epitaxial channel cores, according to some embodiments.

FIGS. 4A-4N illustrate incremental stages for generating an array of 3D NAND flash memory cells with hollow epitaxial channels, according to some embodiments.

FIGS. 5A-5H illustrate incremental stages for generating an array of 3D NAND flash memory cells with hollow epitaxial channels, according to some embodiments.

FIG. 6 illustrates a flowchart of a method for fabricating a 3D NAND memory structure, according to some embodiments.

The drawings are not necessarily to scale. The drawings are merely representations, not intended to portray specific parameters of the disclosure. The drawings are intended to depict exemplary embodiments of the disclosure, and therefore are not to be considered as limiting in scope.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where various embodiments are shown. The methods, systems, and devices may be embodied in many different forms and are not to be construed as being limited to the embodiments set forth herein. Instead, these embodiments are provided so the disclosure will be thorough and complete, and will fully convey the scope of the methods to those skilled in the art.

Embodiments described herein are directed to 3-D NAND devices including hollow epitaxially grown silicon channels formed following a bottom punch scheme, which opens up access to the substrate. More specifically, embodiments herein provide approaches for punching through a stack of alternating layers to provide a reference for epitaxial channel growth in a hollow, or “macaroni” shape. In some embodiments, this bottom punch is performed together with a lateral etch technique to overcome challenges with inter-deck alignment due to high channel aspect ratio. Advantageously, a volume of epitaxial silicon can be reduced using the macaroni shaped epitaxial channel growth of the present disclosure, which makes the threshold voltage less sensitive to trap density fluctuations. Embodiments herein further prevent stack collapse during the lateral etch using support structures, thus providing a low-cost solution to provide the epitaxial reference for crystalline channel growth.

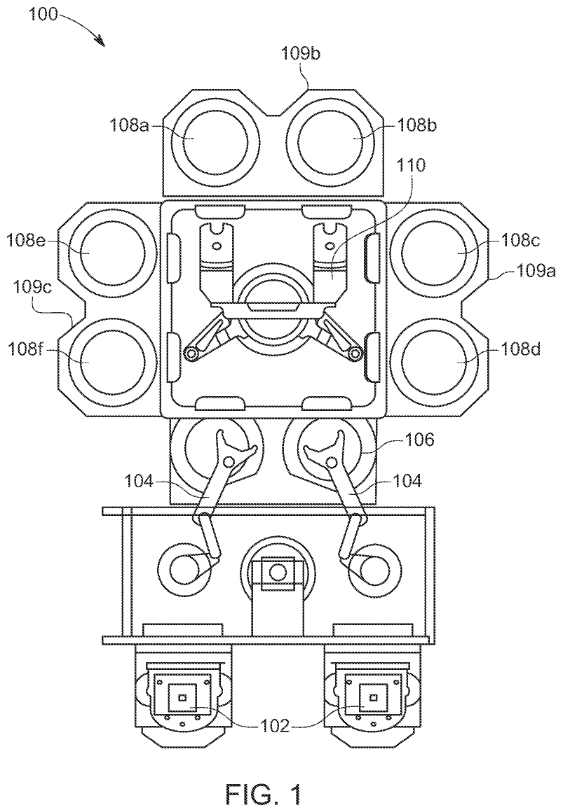

FIG. 1 illustrates a top plan view of one embodiment of a processing system 100 of deposition, etching, baking, and curing chambers according to some embodiments. As shown, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber, 108a-f, can be outfitted to perform a number of substrate processing operations including the etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by the processing system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

The processing system 100, or more specifically, chambers incorporated into the processing system 100 or other processing systems, may be used to produce structures according to some embodiments of the present disclosure. For example, the processing system 100 may be used to produce memory arrays by performing operations such as deposition, etch, sputtering, polishing, cleaning, and so forth, in the various substrate processing chambers 108.

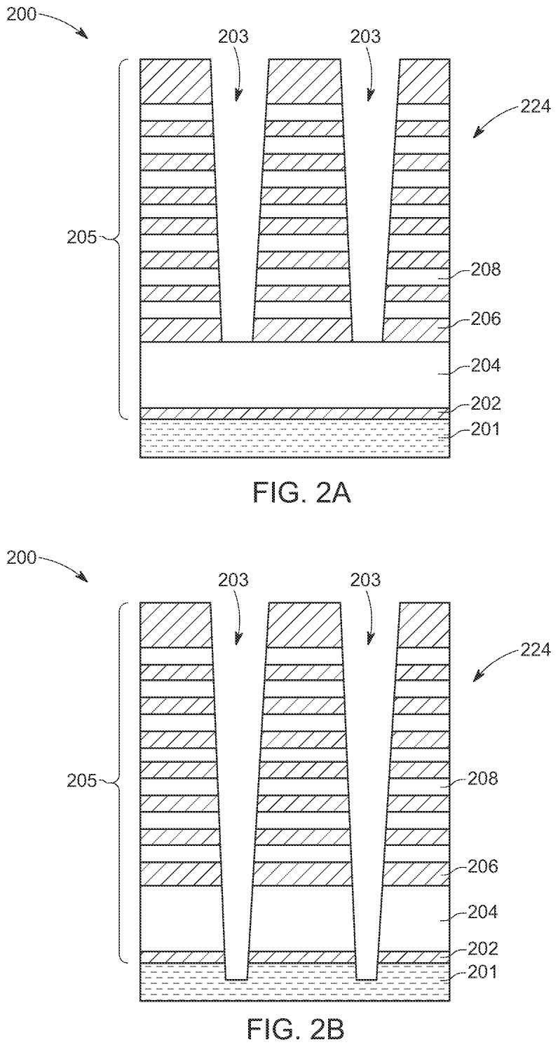

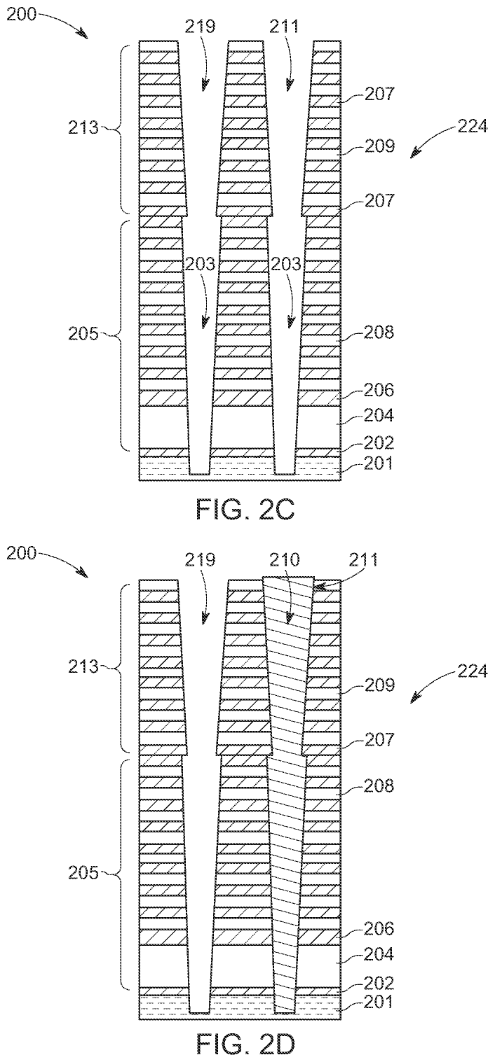

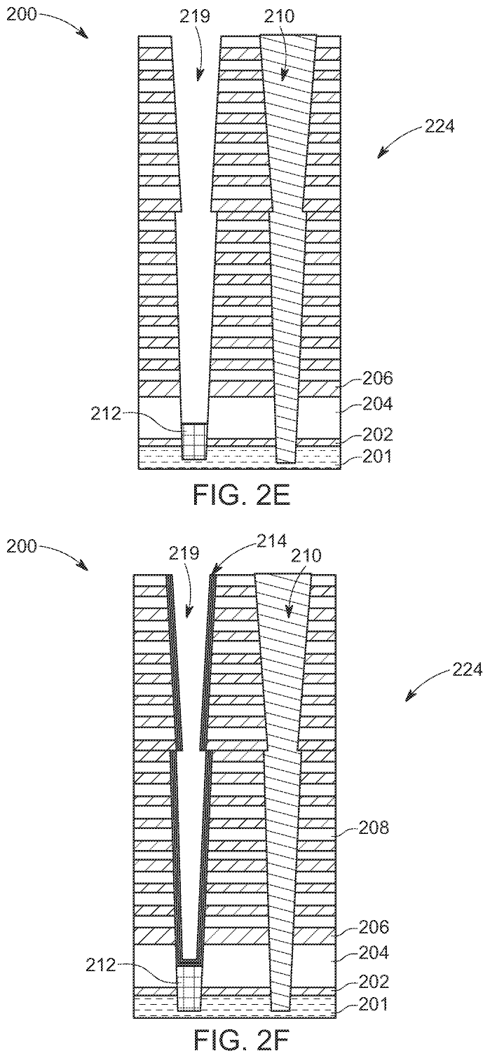

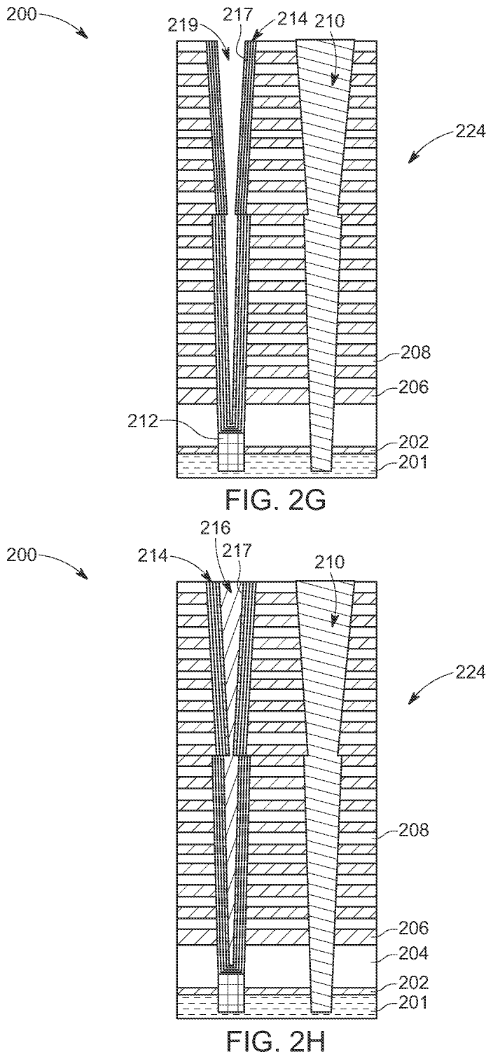

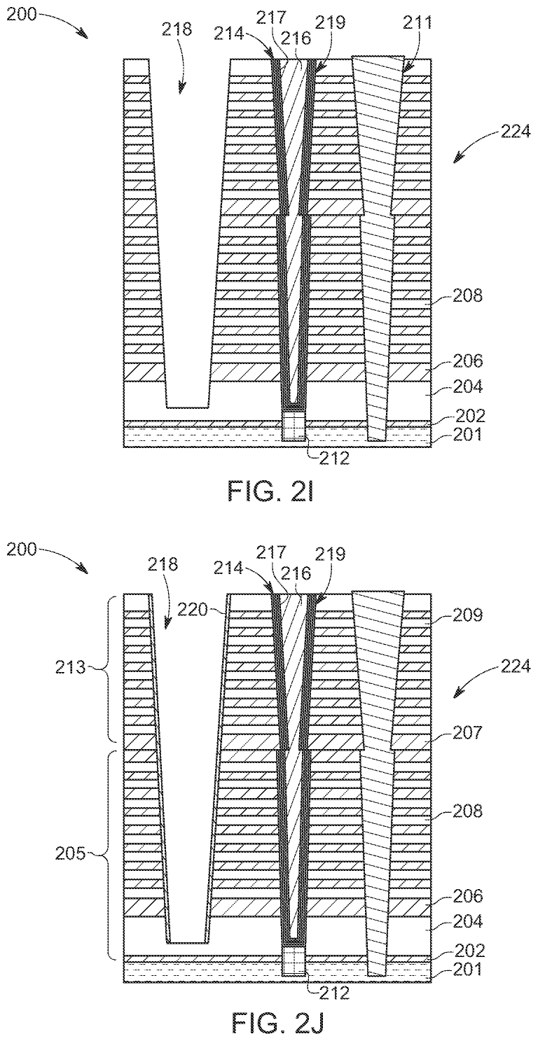

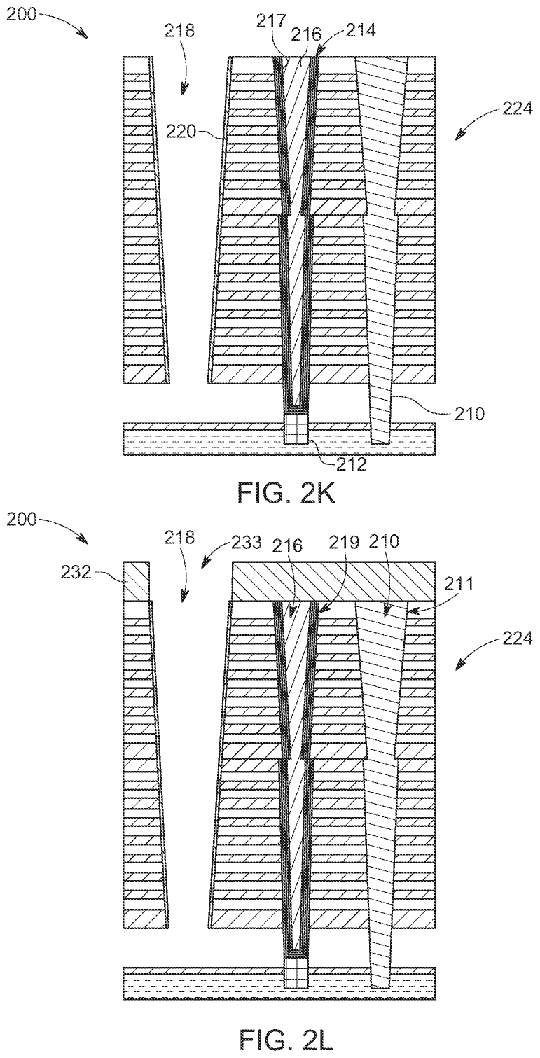

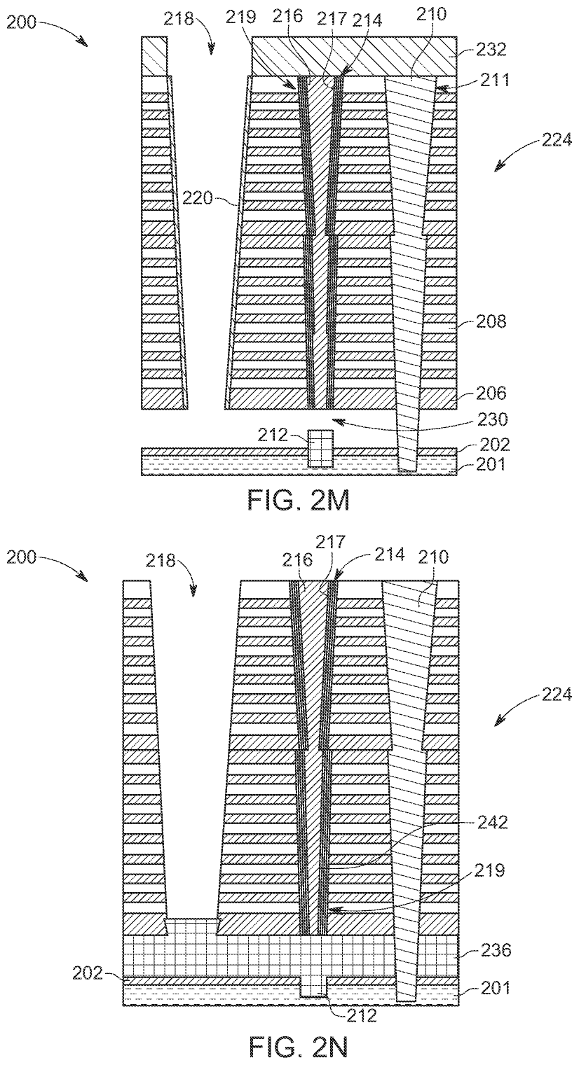

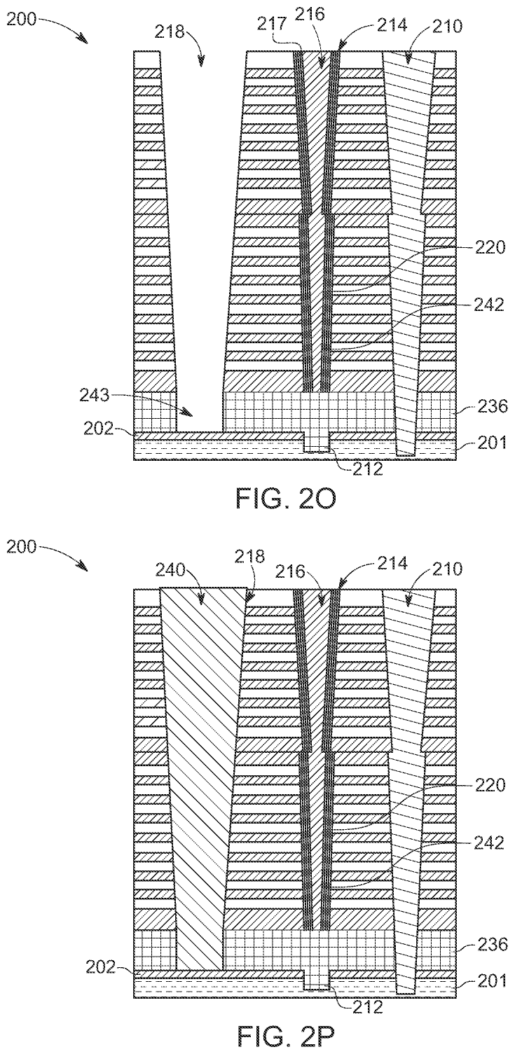

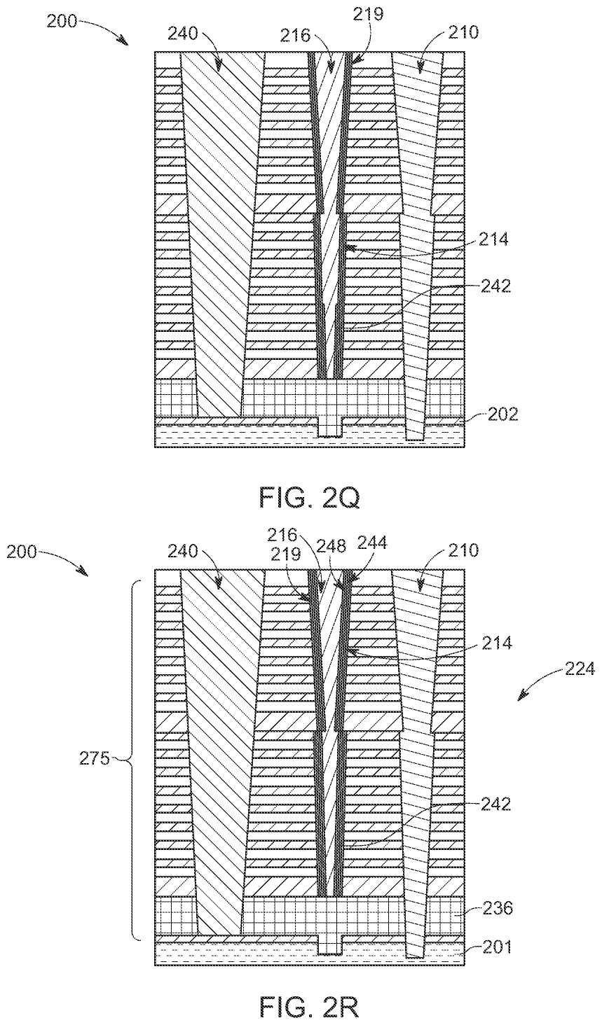

FIG. 2A illustrates a side cross-sectional view of a memory device (hereinafter “device”) 200 at an early stage of processing, according to one or more embodiments described herein. The device 200 may be a partial stack of alternating oxide-nitride layers formed for a 3D NAND flash array, for example. Each of the layers illustrated in FIG. 2A may be formed incrementally, one layer on top of the previous layer using any deposition or layer formation techniques. In this example, the layers may be formed on a substrate 201 of a silicon material, such as an epitaxial silicon or a single-crystal silicon wafer. A silicon oxide layer 202 may be formed over the substrate 201, followed by a silicon nitride layer 204. In some embodiments, the silicon oxide layer 202 and the silicon nitride layer 204 may represent initial layers on the substrate 201, and these layers may be thicker than the alternating oxide-nitride layers formed thereon. Next, alternating layers of silicon oxide 206 and silicon nitride 208 may be formed in a stack.

The progressive formation of the substrate 201, silicon oxide layers 206, silicon nitride layers 208, and other materials described below in FIGS. 2A-2R may be collectively referred to as a stack 224. As illustrated in FIG. 2A, the stack 224 may initially be of a limited height. For example, the finished stack 224 may have a very large number of layers (e.g., 128 pairs of alternating oxide and nitride layers). However, initially forming all of these layers may result in the stack 224 having an aspect ratio that is too high to reliably form the narrow channel holes and other vias that penetrate the entire stack 224. Therefore, the stack 224 may be formed in a series of tiers, wherein the alternating silicon oxide layers 206 and silicon nitride layers 208 correspond to a first tier 205.

As further shown in FIG. 2A, the stack 224 may be etched to form a plurality of channel holes 203 that penetrate the alternating silicon oxide layers 206 and silicon nitride layers 208. The channel holes 203 may be formed by layering a mask (not shown) over the partial stack and performing an etch process to remove material that is exposed by the mask. Any etch process may be used, and some embodiments may use a dielectric etch. Etching through the alternating silicon oxide layers 206 and silicon nitride layers 208 may benefit from a dielectric etch because the desired aspect ratio of the channel holes 203 for the device channels is relatively high (i.e., the vertical depth of the channel holes 203 is relatively large in comparison to the horizontal width of the channel holes 203). Generally, the depth of the channel holes 203 may be controlled based on the number of silicon oxide layers 206 and the number of silicon nitride layers 208 to be etched. For example, a time during which the etch process is allowed to run may be determined by the number of silicon oxide layers 206 and the number of silicon nitride layers 208 along the thicknesses of these layers. For example, some embodiments may etch the channel holes 203 down to the silicon nitride layer 204. Other embodiments may etch the channel holes 203 down to the silicon oxide layer 202, or down to the top of the substrate 201. The non-limiting example illustrated in FIG. 2A stops the etch at the top of the silicon nitride layer 204.

FIG. 2B illustrates how a bottom-punch etch may be used to penetrate the substrate 201 to expose the silicon of the substrate 201, according to some embodiments. The dielectric etch used in FIG. 2B may stop the channel-hole etch before the etch penetrates the substrate 201. Some embodiments may then perform a second etch process such that the channel holes 203 extend down into the substrate 201. This additional etch may be a directional etch oriented vertically towards the bottom of the channel holes 203 and may be referred to herein as a “bottom punch” etch. The bottom punch etch may allow the silicon material of the substrate 201 to be exposed at the bottom of the channel holes 203. In some embodiments, the bottom punch etch may represent a separate etch from the etch used to form the channel holes 203. For example, the bottom punch etch may be performed in a conductor etch chamber instead of a dielectric etch chamber, which may have better critical dimension uniformity and profile tuning than the dielectric etch used to initially form the channel holes 203 for the device channels. The bottom punch may thus extend the channel holes 203 down into the substrate 201 to expose the silicon material. For example, the bottom punch etch may extend to the top surface of the substrate 201, or alternatively may penetrate into the substrate 201 below the top surface of the substrate 201. Alternatively, other embodiments may etch the entire length of the channel holes 203 down into the substrate 201 using a single etch process, thus combining the results of FIGS. 2A-2B into a single processing step. The exposed silicon material of the substrate 201 may be used in later steps to epitaxially grow silicon through the channels that form the 3D NAND flash memory cells.

FIG. 2C illustrates how the stack 224 may be extended by adding a second tier 213 atop the first tier 205, wherein the second tier 213 may include additional silicon oxide layers 207 and silicon nitride layers 209. These additional layers may be formed incrementally on top of the first tier 205. After adding the additional silicon oxide layers 207 and silicon nitride layers 209 of the second tier 213, a plurality of holes 211, 219 may be etched into the second tier 213, as illustrated. Note that these holes 211, 219 may be formed using a similar mask as was previously used to etch the channel holes 203 in the first tier 205. By incrementally etching these layer sets, a very high aspect ratio may be achieved, despite the depth of the holes 211, 219 in the full stack 224.

In practice, the stack 224 may include a large number of layers, a large number of channel holes, and may be used to form many hundreds of 3D NAND flash memory cells. However, these figures have been simplified to show the formation of a single epi silicon channel and the adjacent support structures or slits in the memory array. For example, an actual stack may include thousands of channels, more than 100 alternating oxide and nitride layers, and multiple slits and support structures. These layers may be formed in multiple processes, with etch operations performed incrementally on each batch of layers as they are added to the partial stack. Thus, although FIG. 2B illustrates only two partial stacks being combined, it should be understood that many additional partial stacks may be layered and etched to form the channel holes 203 through the stack 224. For example, some embodiments may include the combination of two partial stacks, each with approximately 128 alternating oxide-nitride layers for a total of 256 alternating oxide-nitride layers.

FIG. 2D illustrates a support feature 210 that may be formed in one of the holes, e.g., hole 211, to provide support to the stack 224 during the subsequent steps of the process, according to some embodiments. The support feature 210 may be selectively deposited in one of the holes in order to form a rigid structure through the first tier 205 and the second tier 213. For example, some embodiments may use a metal, such as tungsten to form the support feature 210. Some embodiments may use a dielectric fill such as a SiOx or a metal-aluminum oxide-nitride-oxide-silicon (MANOS) stack for the support feature 210. Any deposition process may be used to form the support feature 210. Note that the support feature 210 may extend down into the substrate 201 by virtue of the etch process described above that overshoots the last silicon oxide layer 202. As will become apparent later in this disclosure, the support feature 210 keeps the layers of the stack 224 from collapsing when the silicon nitride layer 204 is removed. Furthermore, extending the support feature 210 down into the substrate 201 prevents any movement of the upper layers of the stack 224 when the silicon nitride layer 204 is later removed.

FIG. 2E illustrates an initial layer of epitaxial silicon 212 formed in one of the holes 219, according to some embodiments. As mentioned above, the additional depth of the bottom punch etch into the substrate 201 exposes the silicon material of the substrate 201 to the channel hole 219. Because the single-crystal silicon of the substrate 201 is exposed, the layer of epitaxial silicon 212 may be grown in the channel hole using processes such as silicon epitaxial deposition or epitaxy that grows thin layers of single-crystal silicon over the single-crystal silicon substrate 201. For example, some embodiments may perform the epitaxy process through chemical vapor deposition. Materials such as silicon tetrachloride, trichlorosilane, dichlorosilane, silane, and other chemical sources of silicon may be provided to the deposition chamber to incrementally form the epitaxial silicon 212 that is grown on top of the substrate 201. The height of the epitaxial silicon 212 may be above the silicon oxide layer 202, but below the next silicon oxide layer 206 in the stack 224. For example, the height of the epitaxial silicon 212 may be within the sacrificial nitride layer 204.

FIG. 2F illustrates the deposition of a tunneling layer 214 in the hole 219, according to some embodiments. Since the hole 219 may now be used to form a channel for a vertical column of 3D NAND memory cells, the hole 219 may also be referred to herein as a channel hole 219. The tunneling layer 214 may be formed by depositing a blocking dielectric or oxide, a charge trap nitride (e.g., silicon nitride), and a tunneling dielectric or oxide. These three layers may be collectively referred to as the “tunneling layer” 214 in this disclosure. The oxide layers in the tunneling layer 214 may provide an offset for the conduction band and the valence band for the transistor devices of the memory cells.

In some embodiments, a layer of silicon nitride may be enclosed within inner and outer layers of silicon oxide. The various layers of the tunneling layer 214 may be formed using atomic layer deposition, and thus the layers of the tunneling layer 214 may be relatively thin compared to the alternating oxide-nitride layers of the stack 224. This process may cause the tunneling layer 214 to grow on the sidewalls of the channel hole 219 and along the bottom of the channel hole over the top of the epitaxial silicon 212. Because the epitaxial silicon 212 stops before the alternating silicon oxide layers 206 and silicon nitride layers 208, the interior of the channel for the 3D NAND memory cells may be covered with the tunneling layer 214.

FIG. 2G illustrates deposition of a channel liner 217 formed over the tunneling layer 214 within the channel hole 219. The channel liner 217 may be an aluminum oxide (AlO) formed using atomic layer deposition, and thus may be relatively thin compared to the alternating oxide-nitride layers of the stack 224. This process may cause the channel liner 217 to grow on the tunneling layer 214.

FIG. 2H illustrates how the channel hole 219 may be filled with a core gap fill material 216, according to some embodiments. In order to protect the tunneling layer 214 and the channel liner 217 during subsequent etch processes, the channel hole 219 may be filled with the core gap fill material 216, which may be SiO. As shown, the core gap fill material 216 may be formed directly atop the channel liner 217.

FIG. 2I illustrates a slit 218 that may be etched in the stack 224, according to some embodiments. The slit 218 may represent a relatively long trench that is etched in the stack 224 such that the slit 218 is adjacent to the channel holes 219, 211 along the length of the slit 218. In contrast to the etch process used to form the channel holes 211 and 219, the slit 218 may be etched using a single process that penetrates all the layers of the stack 224. More specifically, the slit 218 may extend into the silicon nitride layer 204. A single process may be used because the slit 218 may be wider than the channel holes. Therefore, the aspect ratio may be less, and therefore achievable in a single process.

FIG. 2J illustrates a slit liner 220 deposited on the interior of the slit 218 to protect the internal silicon oxide layers 206 and silicon nitride layers 208 of the first tier 205 and to protect the additional silicon oxide layers 207 and silicon nitride layers 209 of the second tier 213 from subsequent chemical etch processes that use the slit 218. For example, the slit liner 220 may be deposited on the sidewalls and bottom of the slit 218, and a subsequent etch may be used to remove the slit liner 220 from the bottom of the slit 218 to expose the silicon nitride layer 204. The slit 218 may be used in the memory array of two separate different memory blocks. In later processes, the slit 218 may also provide access to all of the nitride layers in the stack 224 such that these nitride layers can be removed and replaced with tungsten (or any other conductive material) to form conductive pathways for each of the memory cells. These conductive pathways may later form the word lines or gate electrodes for the memory cells. For example, a wet etched using hot phosphoric acid may be used to remove the nitride layers from the stack 224, and the slit 218 may then provide access for the precursors such that an atomic layer deposition process may be used to grow the tungsten in the voids left behind from the removed nitride layers. In some embodiments, the slit liner 220 may be an amorphous silicon (a-Si).

FIG. 2K illustrates the selective removal of the silicon nitride layer 204 (FIG. 2J) of the stack 224, according to some embodiments. In order to grow the epitaxial silicon 212 in the channel holes, the silicon nitride layer 204 may be removed in order to expose the portion of the tunneling layer 214 and the channel liner 217 that need to be removed such that the epitaxial silicon 212 may again be exposed to the channel holes. In this example, a wet etch may be used, such as a hot phosphoric acid chemical etch. The wet etch may access the silicon nitride layer 204 through the slit 218 and remove the silicon nitride layer 204 selectively. The slit liner 220 may protect the internal nitride layers from the etch process. Other embodiments may use dry etches or other processes that are configured to selectively remove the silicon nitride layer 204.

FIG. 2L illustrates a masking layer 232 formed over the stack 224, including over the core gap fill material 216 within channel hole 219 and over the support feature 210 within channel hole 211. As shown, an opening 233 may be provided through the masking layer 232, wherein the opening 233 is aligned with the slit 218.

FIG. 2M illustrates the selective removal of the tunneling layer 214 and the channel liner 217 from the bottom of channel hole 219 to form a gap 230 between the epitaxial silicon 212 and the bottom silicon oxide layer 206. A lateral wet etch process may be used to selectively remove the tunneling layer 214 and the channel liner 217. As shown, the channel liner 217 may also be partially recessed up into the channel hole 219. Partial removal of the channel liner 217 leaves the channel hole 219 lined by the tunneling layer 214 and exposed to the epitaxial silicon 212.

Note that the gap 230 left behind from the removal of the nitride layer the tunneling layer 214 and the channel liner 217 is lined on the top and bottom by oxide layers (e.g., oxide layer 202 and bottom silicon oxide layer 206). These oxide layers may be formed such that they are slightly thicker than the other oxide layers in the stack 224. However, because the oxide and nitride layers in the tunneling layer 214 and the channel liner 217 may be formed as atomic layer deposition layers, these layers will be relatively thin, such that they can be removed without removing a significant portion of the other oxide layers that may be exposed to the etch process.

FIG. 2N illustrates the growth of the epitaxial silicon 212, according to some embodiments. The epitaxy process may be executed as described above. However, because the slit 218 and the channel hole 219 are exposed to the epitaxial silicon 212, a layer of epitaxial silicon 236 may be grown to fill the gap 230 (FIG. 2M) and begin to fill the channel hole 219. More specifically, the layer of epitaxial silicon 236 may extend along the tunneling layer 214 to form an epitaxial core layer 242 within a lower portion of the channel hole 219. The growth of the layer of epitaxial silicon 236 may stop when the channel liner 217 is reached in order to prevent the slit 218 from also being filled with the layer of epitaxial silicon 236.

FIG. 2O illustrates the selective removal of a portion 243 of the layer of epitaxial silicon 236 at the bottom of the slit 218. The portion 243 of the layer of epitaxial silicon 236 may be removed using an etch process to perform a bottom “punch” as described above. This etch may remove the portion 243 of the layer of epitaxial silicon 236 until the bottom oxide layer 202 is exposed. Alternatively, the etch may go through the bottom oxide layer 202 and into the substrate 201.

FIG. 2P illustrates the deposition of a sacrificial gap fill material 240 in the slit 218, according to some embodiments. The sacrificial gap fill material 240 may be deposited in the slit 218, including within the portion 243 of the layer of epitaxial silicon 236, such that the epitaxial silicon 236 may be grown in the channel hole 219 without filling the slit 218. In some embodiments, the sacrificial gap fill material 240 is formed directly atop the bottom oxide layer 202.

FIG. 2Q illustrates removal of the remainder of the channel liner 217 (FIG. 2P) from the channel hole 219. As shown, the channel liner 217 is removed from along the tunneling layer 214, in an area over the epitaxial core layer 242. In some embodiments, the core gap fill material 216 remain in place, and the channel liner 217 removed from the top of the channel hole 219.

FIG. 2R illustrates the epitaxial growth of the epitaxial silicon 236 up through the channel hole 219, according to some embodiments. An epitaxy process may be carried out as described above to further grow the epitaxial core layer 242 up through the channel hole 219, e.g., in the area vacated by the channel liner 217. The resulting structure may include the stack 224 with channel hole 219 that is filled with a hollow epitaxial silicon core 244 having a “macaroni” structure. The hollow epitaxial silicon core (hereinafter “epi core”) 244 may be formed between the tunneling layer 214 and the core gap fill material 216. As shown, the epi core 244 may be physically connected with the substrate 201, the epitaxial silicon 212, and the tunneling layer 214.

Referring still to FIG. 2R, the device 200 (e.g., 3D NAND memory structure) may include the silicon substrate 201, which may be formed with a single-crystal silicon. The device may also include a plurality of alternating material layers 275 arranged in a vertical stack on the silicon substrate 201. The alternating material layers 275 may include alternating layers of an oxide material and a nitride material (e.g., silicon oxide and silicon nitride). At later stages in the manufacturing process, the alternating material layers 275 may instead include alternating layers of an oxide material and a metal, such as tungsten. For example, the nitride material may be selectively removed and replaced with the metal to form the gate electrodes for individual memory cells in the memory structure.

The channel hole 219 may extend through the plurality of alternating material layers 275 to the silicon substrate 201. This channel hole 219 may be formed using any of the processes described throughout this disclosure. As illustrated, the channel hole 219 may be approximately perpendicular to the plurality of alternating material layers 275. The device 200 may also include a channel 248 inside the channel hole 219. The channel may include the tunneling layer 214 around the interior of the channel hole 219 (and consequently around the exterior of the channel) using the layers described above. The channel 248 may also include the hollow epi core 244 inside the tunneling layer 214 that contacts the silicon substrate 201. In some cases, the epi core 244 may extend into the silicon substrate 201, such that the epi core 244 begins its epitaxial growth below the top level of the silicon substrate 201. In some embodiments, the channel 248 may further include the core gap fill material 216 within the epi core 244.

The device 200 may also include the layer of epitaxial silicon 236 that extends beyond the channel hole 219, the layer of epitaxial silicon 236 being parallel to the plurality of alternating material layers 275. Although FIG. 2R shows only one channel of many channels in the device 200, the layer of epitaxial silicon 236 may connect the epi core 244 of the illustrated channel 248 to a plurality of other channels in the device 200. For example, the epi cores of each channel connected by the layer of epitaxial silicon 236 may be grown simultaneously during the same epitaxy process from the layer of epitaxial silicon 236.

The process described above may be used to selectively grow the epi core 244 using the single-crystal silicon of the substrate 201. The 3D NAND flash memory cells that use the hollow, “macaroni” shaped epi core 244 advantageously reduce the volume of epitaxial Si and make threshold voltage less sensitive to the trap density fluctuation.

Further processes may be later be performed on the stack 224 to complete the memory array. Although these operations are beyond the scope of this disclosure, they may include removing the sacrificial gap fill material 240 from the slit, removing the nitride layers in the stack 224, depositing conductive metal (e.g., tungsten) in place of the nitride layers to form the gate electrodes, performing a staircase etch on the stack 224, and so forth.

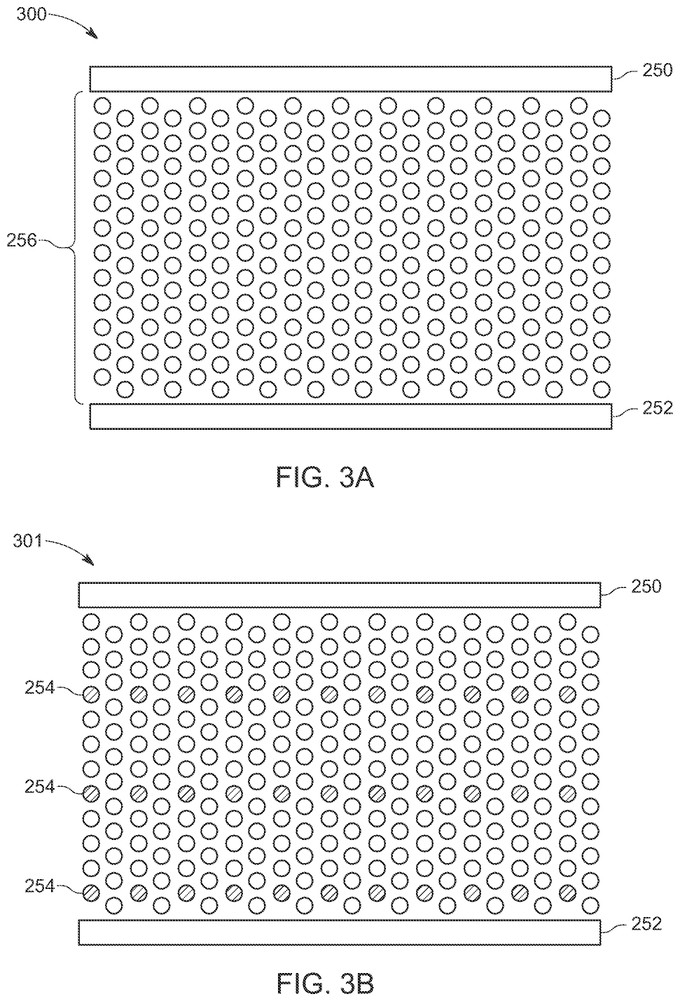

FIG. 3A illustrates a portion of a memory array 300, according to some embodiments. This portion of the memory array 300 may represent a single memory block with offset rows of channels 256. Slits 250, 252 may be used to separate this memory block from other memory blocks. This example uses 24 channels arranged into offset columns between the slits 250, 252. This portion of the memory array 300 may use traditional oxide or polysilicon cores for the channels. Therefore, no support structures may be needed, and each of the channel holes may be used to implement memory cells.

In comparison, FIG. 3B illustrates a portion of a memory array 301 when the some of the channels have been used for support structures to facilitate the epitaxial silicon channel cores, according to some embodiments. As described above, the process for growing the epitaxial silicon channels for memory cells in the memory array 301 may use a process where some of the channel holes are used for support structures 254 to prevent the memory array 301 from collapsing when the sacrificial nitride layer is removed to make room for the epitaxial silicon layer. These support structures 254 may be spaced throughout the memory array in order to provide adequate support for the layer stack in the array during the manufacturing process. Note that the spacing illustrated in FIG. 3B is provided only by way of example and is not meant to be limiting. In this example, the spacing of the support structures 254 is about every four channel holes and every other column. This configuration does slightly reduce the bit density per area in the memory array 301 by using some of the channel holes for support structures 254 that would otherwise be used for memory cells.

As described above, some embodiments may use channel holes in order to provide support structures during the manufacturing process. An advantage of using channel holes for support structures includes the ability to increase or decrease the spacing of the support structures as needed. However, some embodiments may instead form the same epitaxial silicon channels by using the slits instead of the channel holes to provide the support structures. These embodiments trade off the amount support provided across the memory block in exchange for an increase in the channel density.

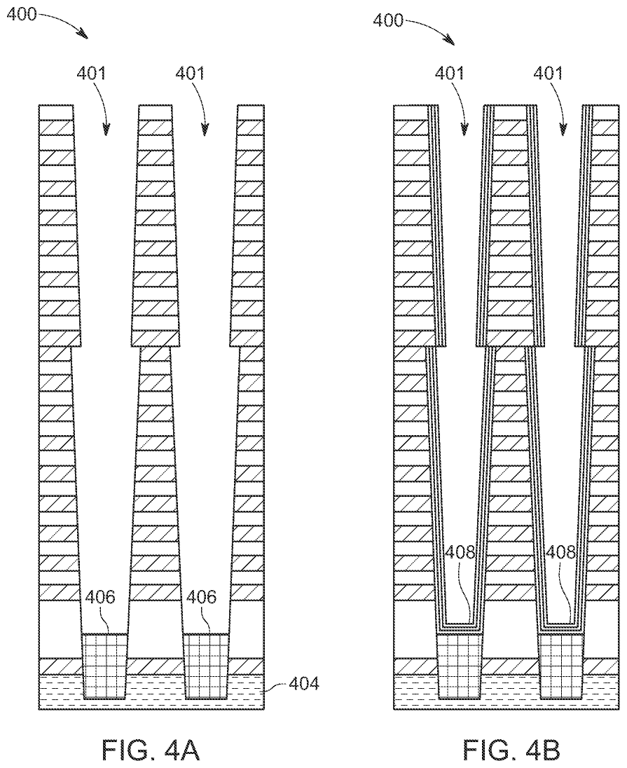

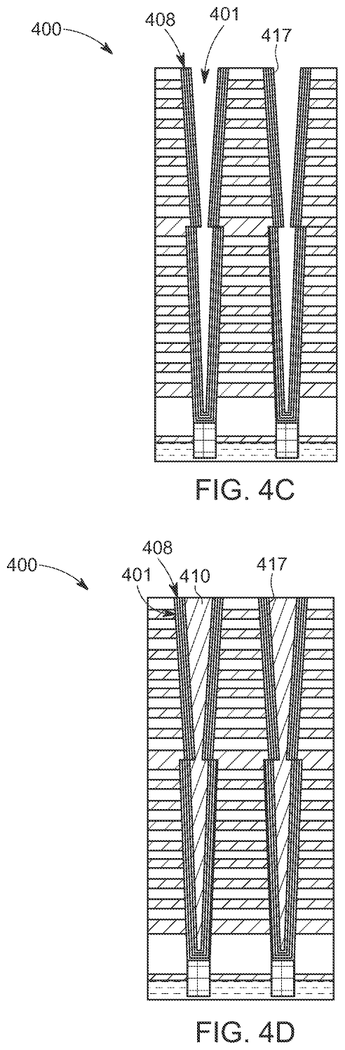

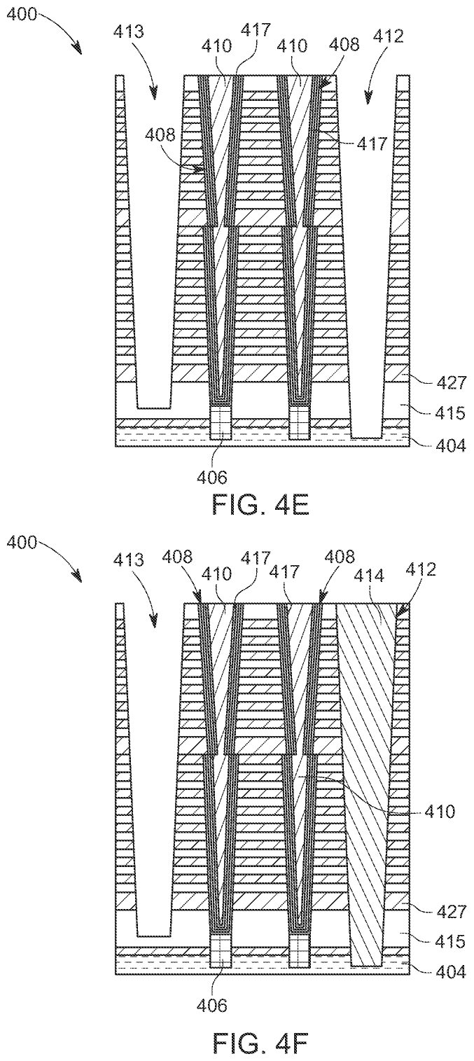

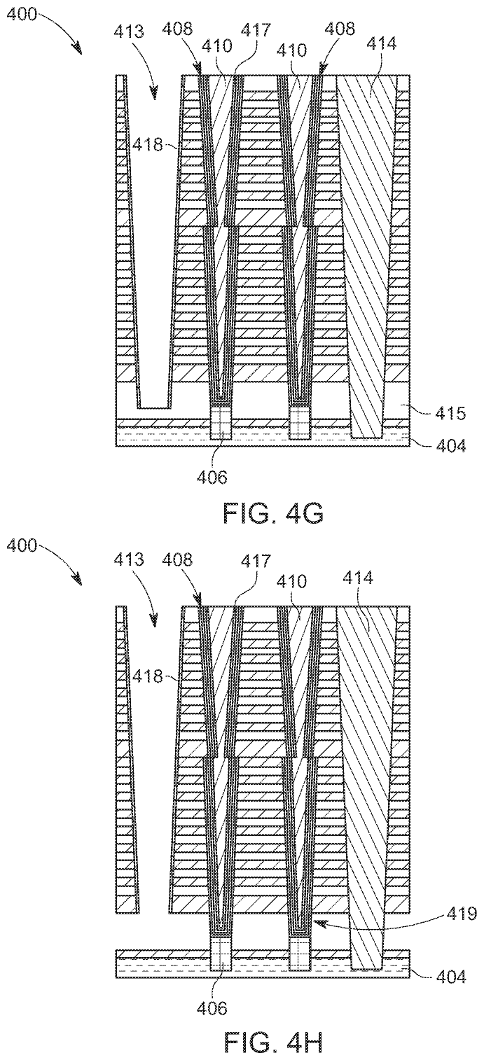

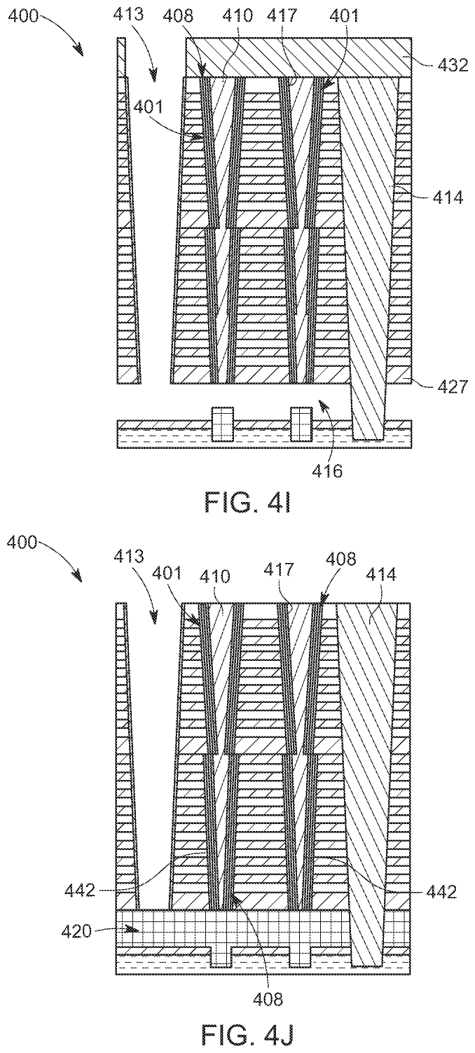

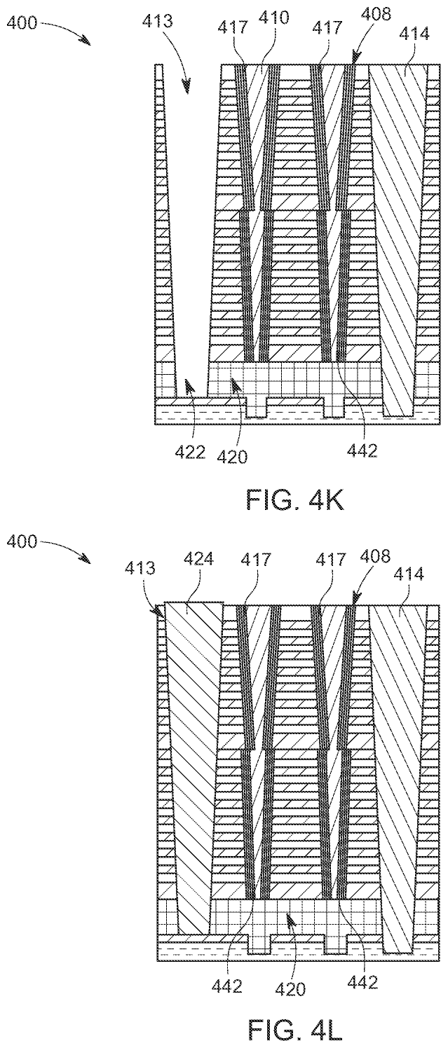

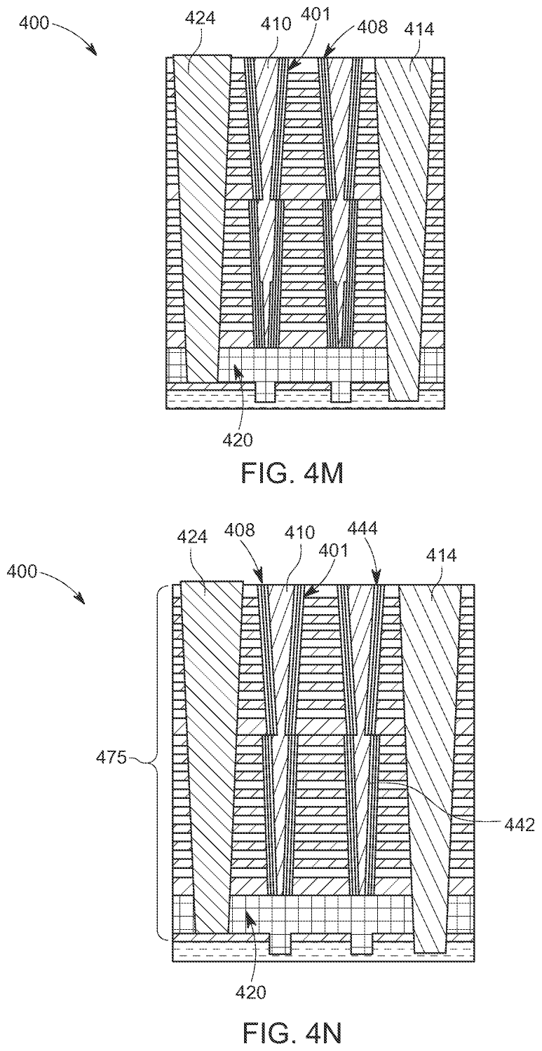

FIGS. 4A-4N illustrate incremental steps in a fabrication process for a memory structure that use the slits that separate the memory blocks for support structures when growing the epitaxial silicon channels for the individual memory cells, according to some embodiments. FIG. 4A illustrates channel holes 401 in a stack 400 that have epitaxial silicon 406 grown from the substrate 404, according to some embodiments. The channel holes 401 and the epitaxial silicon 406 may be formed using the process described above in relation to FIGS. 2A-2E. In some embodiments, the epitaxial silicon 406 may be formed after the channel holes 401 are formed in the first set of oxide/nitride layers and before the upper sets of oxide/nitride layers are formed and etched to extend the channel holes 401. For example, turning back to FIG. 2B, after the channel holes 203 have been etched and the bottom punch etch has been used to extend the channel holes 203 into the substrate 201, the epitaxial silicon 406 may be grown in the channel holes 203 at this stage from the exposed substrate 201. After the epitaxial silicon 406 has been formed in the holes 203, the upper alternating layers of oxide 207 and nitride 209 may be added and etched to increase the number of device layers and the depth of the channel holes 203, to eventually form the structure illustrated in FIG. 4A. Alternatively, the epitaxial silicon 406 may be grown after the channel holes 401 have been completely formed, or at any stage after the silicon of the substrate 404 has been exposed.

FIG. 4B illustrates the channel holes 401 after being lined with a tunneling layer 408. The tunneling layer 408 may be formed as described in detail above in relation to FIG. 2H. FIG. 4C illustrates the channel holes 401 after being further lined with a channel liner 417. The channel liner 417 may be formed as described in detail above in relation to FIG. 2G. FIG. 4D illustrates the channel holes 401 filled with a sacrificial gap fill material 410, which may be formed as described in detail above in relation to FIG. 2H.

FIG. 4E illustrates slits 412, 413 formed on either side of the memory block, according to some embodiments. It should be understood that although only two channel holes are illustrated, many additional channels may also be present between the slits 412, 413. For example, the slits 412, 413 may enclose a memory block with a block width of 24 channels. These channels may be arranged in a honeycomb pattern of two offset rows of 12 channels each. Multiple pairs of these offset rows of 24 channels may be present in the block. As shown, slit 413 is etched to a depth below first oxide layer 427 and within the sacrificial nitride layer 415. However, in order to provide a support structure when later fabricating the epitaxial silicon layer and channel cores, a slit may undergo an additional or extended etch process to increase the depth of the slit. For example, slit 412 may be etched to a depth that is below the top of the substrate 404 using a bottom-punch etch. This allows the slit 412 to act as a support structure that is anchored to the substrate 404 instead of being allowed to float on top of the substrate 404.

FIG. 4F illustrates the slit 412 filled with a gap fill material 414, according to some embodiments. In this example, alternating slits may be used as support structures in the memory array. Thus, slit 413 may remain at a shallower depth, while slit 412 may be etched to the depth below the substrate 404 and filled with the gap fill material 414, which may act as the support structure during subsequent growth of the epitaxial silicon layer.

FIG. 4G demonstrates a slit liner 418, which may be deposited on the interior of the slit 413, and a subsequent etch, which may be used to remove the slit liner 418 from the bottom of the slit 413 to expose the sacrificial nitride layer 415. The slit liner 418 may be formed as described in detail above in relation to FIG. 2J.

FIG. 4H illustrates the removal of the sacrificial nitride layer 415, according to some embodiments. As described above in relation to FIG. 2K, the sacrificial nitride layer 415 may be exposed to an etch process through the slit 413 to selectively remove the sacrificial nitride layer 415. Removal of the sacrificial nitride layer 415 exposes a lower portion 419 of the tunneling layer 408 in an area above the epitaxial silicon 406 grown from the substrate 404.

FIG. 4I illustrates formation of a masking layer 432 atop the device 400, and the removal of the sacrificial nitride layer 415. In some embodiments, the channel liner 417 may be partially recessed up into the channel holes 401. The sacrificial nitride layer 415 and the channel liner 417 may be removed as described in detail above in relation to FIG. 2M. After the removal of the exposed portion 419 (FIG. 4H) of the tunneling layers 408 and the channel liner 417 at the bottom of the channel holes 401, the gap fill material 414 may provide a support structure for the stack 400 to keep the stack 400 from collapsing after exposing a gap 416 between the substrate 404 and the first oxide layer 427.

FIG. 4J illustrates the epitaxial growth of an epitaxial silicon layer 420 in the gap 416. As described above, the epitaxial silicon layer 420 may be grown until it begins to fill the channel holes 401, e.g., in the area where the channel liner 417 has been removed. More specifically, the epitaxial silicon layer 420 may extend along the tunneling layer 408 to form an epitaxial core layer 442 within a lower portion of the channel holes 401.

FIG. 4K illustrates the formation of a hole 422 in the epitaxial silicon layer 420 to extend the slit 413 using a bottom-punch etch process, while FIG. 4L illustrates the slit 413 filled with a gap fill material 424. These steps may be performed as described in detail above in relation to FIG. 2O and FIG. 2P.

FIG. 4M illustrates further removal of the channel liner 417 from the channel holes 401, while FIG. 4N illustrates epitaxial growth of the epitaxial silicon layer 420 up through the channel holes 401, according to some embodiments. An epitaxy process may be carried out as described above to further grow the epitaxial core layer 442 up through the channel holes 401, e.g., in the area vacated by the channel liner 417. The resulting structure may include a hollow epitaxial silicon core 444 having a “macaroni” structure. The hollow epitaxial silicon core (hereinafter “epi core”) 444 may be formed between the tunneling layer 408 and the sacrificial gapfill material 410. As shown, the epi core 444 may be physically connected with the substrate 404 and the tunneling layer 408.

The channels in the resulting stack 400 illustrated in FIG. 4N may be substantially the same as the channels in the resulting stack 224 in FIG. 2R, with alternating material layers 475 and channel holes 401 that are each lined with tunneling layers 408 and filled with the epi core 444. As further shown, the sacrificial gapfill 410 material may be present within the epi core 444. However, in the memory structure that includes this stack 400, none of the channels need to be set aside as support structures. Instead, the maximum channel density may be achieved by using the slits as support structures during the fabrication process. As described above, additional process steps that are beyond the scope of this disclosure may subsequently be performed on the stack 400 to complete the fabrication of the memory structure, such as removal of the alternating nitride layers, formation of conductive layers (e.g., tungsten layers) to form gate electrodes, execution of a staircase etch, and so forth.

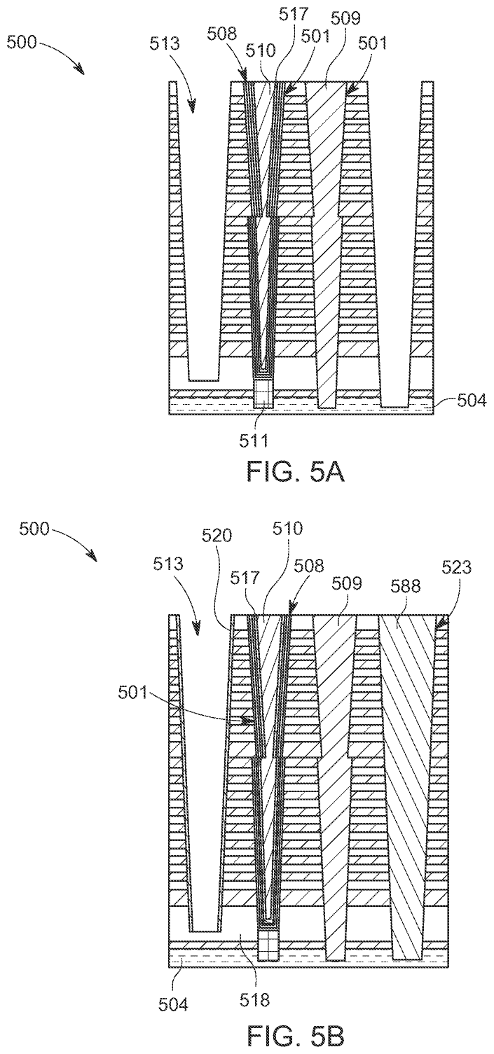

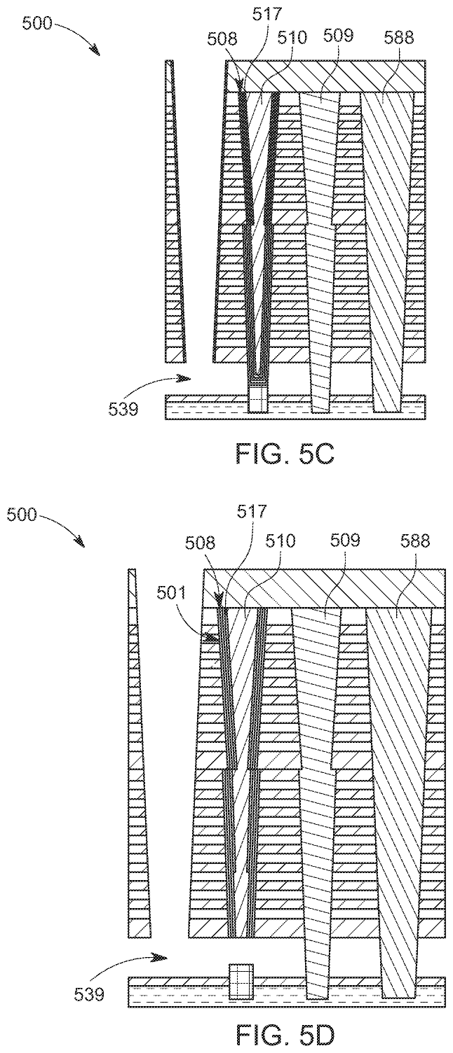

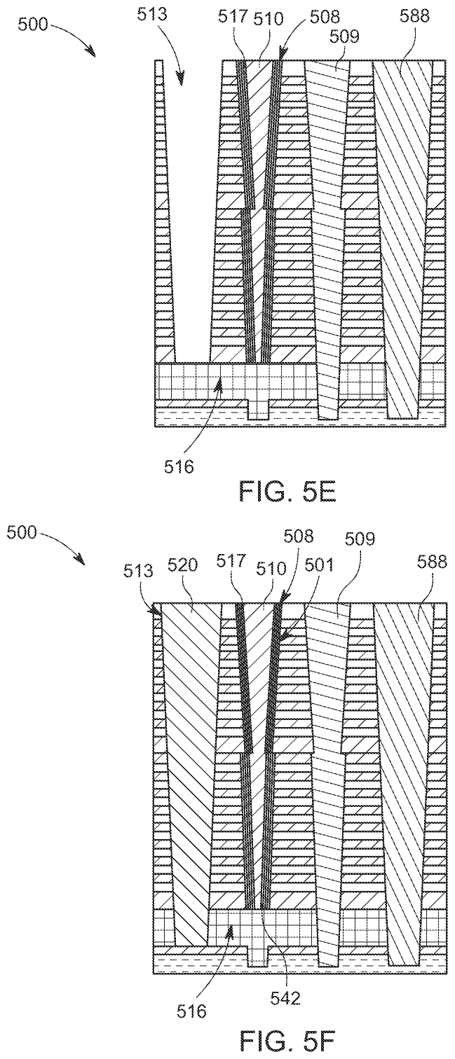

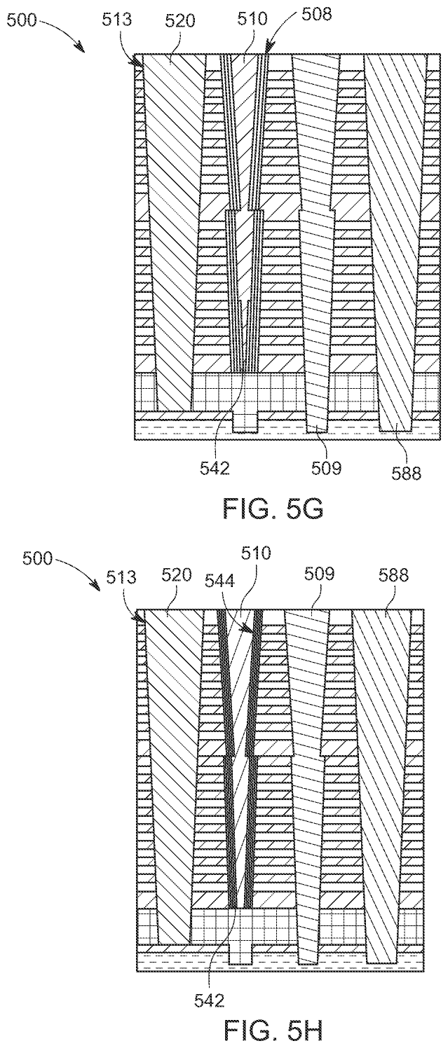

FIGS. 5A-5H illustrate incremental steps in a fabrication process for a memory structure that uses the slits that separate the memory blocks for support structures when growing the epitaxial silicon channels for the individual memory cells, according to some embodiments. FIG. 5A illustrates a stack 500 formed using the processes described above in relation to FIGS. 4A-4F. As further shown, a first channel hole 501 may be formed through the layers of the stack 500, and then filled with a support structure 509. A second channel hole 501 may be filled with a gap fill material 510, a tunneling layer 508, and a channel liner 517 that separates the gap fill material 510 from epitaxial silicon 511 that is grown from the substrate 504. The stack 500 may further include a slit 513 and a slit 523. Note that many additional channel holes may also be present in the stack 500 that are not visible in FIG. 5A.

As shown in FIG. 5B, a slit liner 520 may be present within the slit 513, the slit liner 520 being etched down to a level above the substrate 504 for contact with a sacrificial nitride layer 518. The slit 523 may be filled with a gap fill material 588 and may extend down into the substrate 504 to act as a support structure.

The remaining steps to grow the epitaxial silicon into the channels of the stack 500 may be carried out as described in detail above. For example, FIG. 5C illustrates the removal of the sacrificial nitride layer 518 to expose a gap 539 while the stack 500 is supported by the support structures. FIG. 5D illustrates removal of the portions of the tunneling layer 508 and the channel liner 517 that are exposed in the gap 539. The channel liner 517 may be recessed up into the second channel hole 501. FIG. 5E illustrates the growth of an epitaxial silicon layer 516 in the gap 539, while FIG. 5F illustrates the result of a bottom-punch through the epitaxial silicon layer 516 followed by formation of a gap fill material 520 in the slit 513. FIG. 5F further illustrates partial growth of an epitaxial core layer 542 in the first channel hole 501. FIG. 5G illustrates removal of the channel liner 517, while FIG. 5H illustrates further growth of the epitaxial core layer 542 to form hollow epitaxial silicon core 544.

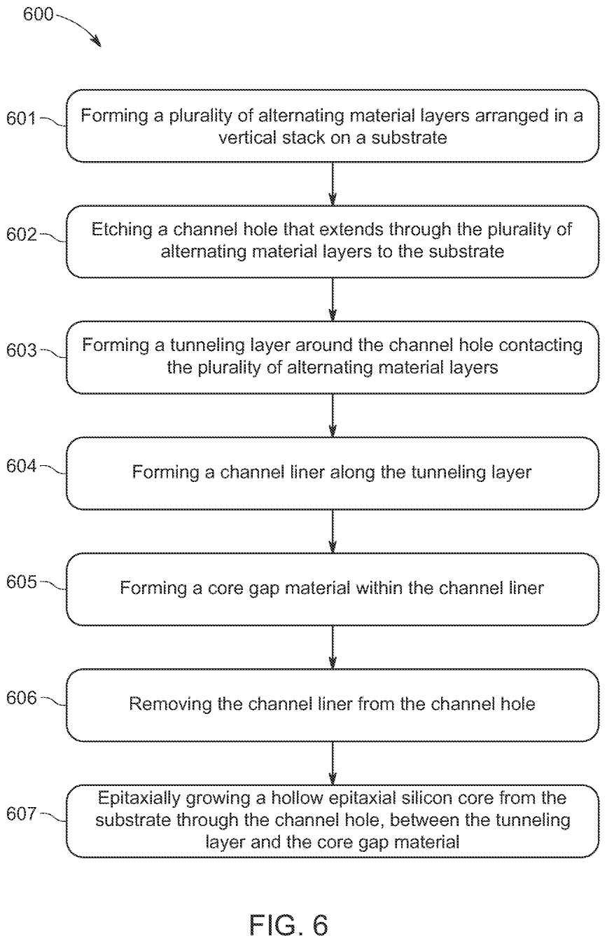

FIG. 6 illustrates a flowchart 600 of a method for fabricating a 3D NAND memory structure, according to some embodiments. This method may be executed in various processing chambers in a semiconductor processing system, e.g., as illustrated in FIG. 1.

At block 601, the method may include forming a plurality of alternating material layers arranged in a vertical stack on a substrate. In some embodiments, the alternating material layers include alternating layers of an oxide material and a nitride material. In some embodiments, the alternating material layers include alternating layers of the oxide material and a metal, wherein the metal forms a gate electrode for individual memory cells.

At block 602, the method may include etching a channel hole that extends through the plurality of alternating material layers to the substrate.

At block 603, the method may include forming a tunneling layer around the channel hole contacting the plurality of alternating material layers. In some embodiments, the tunneling layer may include a blocking dielectric or oxide layer, a charge trap nitride layer, and a dielectric or oxide layer.

At block 604, the method may include forming a channel liner along the tunneling layer. In some embodiments, the channel liner may be AlO deposited via ALD.

At block 605, the method may include forming a core gap material within the channel liner. In some embodiments, the core gap material may be SiO, which fills the channel hole.

At block 606, the method may include removing the channel liner from the channel hole. In some embodiments, removing the channel liner from the channel hole includes recessing a first portion of the channel liner from a lower section of the channel hole.

At block 607, the method may include epitaxially growing a hollow epitaxial silicon core from the substrate through the channel hole, between the tunneling layer and the core gap material. In some embodiments, an epitaxial core layer is first grown within the lower section of the channel hole following removal of the first portion of the channel liner from the lower section of the channel hole.

It should be appreciated that the specific steps illustrated in FIG. 6 provide particular methods of fabricating a 3D NAND memory structure according to various embodiments. Other sequences of steps may also be performed according to alternative embodiments. For example, alternative embodiments may perform the steps outlined above in a different order. Moreover, the individual steps illustrated in FIG. 6 may include multiple sub-steps that may be performed in various sequences as appropriate to the individual step. Furthermore, additional steps may be added or removed depending on the particular applications. Many variations, modifications, and alternatives also fall within the scope of this disclosure.

In various embodiments, design tools can be provided and configured to create the datasets used to pattern the semiconductor layers of the device, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A three-dimensional (3D) NAND memory structure comprising:
a silicon substrate;
a plurality of alternating material layers arranged in a vertical stack on the silicon substrate, wherein a channel hole extends through the plurality of alternating material layers to the silicon substrate, and wherein the channel hole is perpendicular to the plurality of alternating material layers; and
a channel inside the channel hole, wherein the channel comprises:
a tunneling layer around an interior of the channel hole, the tunneling layer contacting the plurality of alternating material layers; and
a hollow epitaxial silicon core inside the tunneling layer, wherein the hollow epitaxial silicon core contacts the silicon substrate.

2. The 3D NAND memory structure of claim 1, wherein the silicon substrate comprises a single-crystal silicon from which the hollow epitaxial silicon core is grown through the channel hole.

3. The 3D NAND memory structure of claim 1, wherein the plurality of alternating material layers comprise alternating layers of an oxide material and a nitride material.

4. The 3D NAND memory structure of claim 1, wherein the plurality of alternating material layers comprise alternating layers of an oxide material and a metal, wherein the metal forms a gate electrode for individual memory cells.

5. The 3D NAND memory structure of claim 1, wherein the hollow epitaxial silicon core extends into the silicon substrate.

6. The 3D NAND memory structure of claim 1, further comprising a layer of epitaxial silicon that extends beyond the channel hole, wherein the layer of epitaxial silicon is between the silicon substrate and the plurality of alternating material layers, and the layer of epitaxial silicon connects the hollow epitaxial silicon core to a plurality of other channels.

7. The 3D NAND memory structure of claim 6, further comprising a support structure that extends through the plurality of alternating material layers and the layer of epitaxial silicon, wherein the support structure extends into the silicon substrate.

8. A method of fabricating a three-dimensional (3D) NAND memory structure, the method comprising:
forming a plurality of alternating material layers arranged in a vertical stack on a substrate;
etching a channel hole through the plurality of alternating material layers to the substrate;
forming a tunneling layer around the channel hole, the tunneling layer contacting the plurality of alternating material layers;
forming a channel liner along the tunneling layer;
forming a core gap material within the channel liner;
removing the channel liner from the channel hole; and
epitaxially growing a hollow epitaxial silicon core from the substrate through the channel hole, between the tunneling layer and the core gap material.

9. The method of claim 8, further comprising etching a slit in the memory structure, wherein the slit extends through the plurality of alternating material layers and into a sacrificial nitride layer, and wherein the sacrificial nitride layer is above the substrate.

10. The method of claim 9, further comprising selectively etching the sacrificial nitride layer to expose a portion of the tunneling layer and the channel liner.

11. The method of claim 10, further comprising removing the portion of the tunneling layer and the channel liner.

12. The method of claim 10, further comprising epitaxially growing an epitaxial silicon layer above the substrate after the portion of the tunneling layer and the channel liner are removed.

13. The method of claim 8, further comprising:
etching a second channel hole through the plurality of alternating material layers, wherein the second channel hole extends into the substrate; and
filling the second channel hole with a gap fill material to support the vertical stack.

14. The method of claim 8, wherein removing the channel liner from the channel hole comprises recessing a first portion of the channel liner from a lower section of the channel hole, and wherein an epitaxial core layer is epitaxially grown within the lower section of the channel hole.

15. A method of fabricating a hollow epitaxial silicon core of a three-dimensional (3D) NAND memory structure, the method comprising:
forming a plurality of alternating material layers arranged in a vertical stack on a silicon substrate;
etching a channel hole that extends through the plurality of alternating material layers to the silicon substrate;
forming a tunneling layer around the channel hole, wherein the tunneling layer contacts the plurality of alternating material layers;
forming a channel liner around the tunneling layer;
forming a core gap material within the channel liner;
removing the channel liner from the channel hole; and
epitaxially growing the hollow epitaxial silicon core from the silicon substrate through the channel hole, between the tunneling layer and the core gap material.

16. The method of claim 15, further comprising etching a slit in the memory structure through the plurality of alternating material layers, wherein the slit extends into a sacrificial nitride layer, and wherein the sacrificial nitride layer is above the silicon substrate.

17. The method of claim 16, further comprising selectively etching the sacrificial nitride layer to expose a portion of the tunneling layer and the channel liner.

18. The method of claim 17, further comprising removing the portion of the tunneling layer and the channel liner to form a gap between the silicon substrate and the channel liner.

19. The method of claim 18, further comprising epitaxially growing an epitaxial silicon layer from the silicon substrate, wherein the epitaxial silicon layer extends into the gap.

20. The method of claim 15, wherein removing the channel liner from the channel hole comprises recessing a first portion of the channel liner from a lower section of the channel hole, and wherein an epitaxial core layer is epitaxially grown within the lower section of the channel hole.
